(19) United States
(12) Patent Application Publication
(10) Pub. No.: US 2014/0085620 A1
(43) Pub. Date: Mar. 27, 2014

(54) 3D PRINTER WITH SELF-LEVELING PLATFORM

(71) Applicants: Maxim Lobovsky, Cambridge, MA (US); Ian Ferguson, Cambridge, MA (US); Yoav Reches, London (GB); Jason Livingston, Somerville, MA (US)

(72) Inventors: Maxim Lobovsky, Cambridge, MA (US); Ian Ferguson, Cambridge, MA (US); Yoav Reches, London (GB); Jason Livingston, Somerville, MA (US)

(21) Appl. No.: 13/848,979

(22) Filed: Mar. 22, 2013

Related U.S. Application Data
(60) Provisional application No. 61/704,937, filed on Sep. 24, 2012.
(60) Provisional application No. 61/792,053, filed on Mar. 15, 2013.

(51) Int. Cl. G03F 7/20

(52) U.S. Cl. CPC G03F 7/70775
USPC 355/72

(57) ABSTRACT

3D printing systems and methods avoid build-compromising misalignments through the use of a self-leveling assembly that maintains a constant and typically fully parallel orientation between a build platform and the bottom surface of a resin tank. As a result, contact between the floor of the resin tank and the build platform surface may be uniformly flat and even, and perpendicular to the z-axis motion of the deposition source.

### CROSS-REFERENCE TO RELATED APPLICATIONS

This application claims priority to, and the benefits of, U.S. Provisional Application Ser. Nos. 61/792,053, filed on Mar. 15, 2013, and 61/704,937, filed on Sep. 24, 2012, the entire disclosures of which are hereby incorporated by reference.

### BACKGROUND

Three-dimensional (3D) printers build a solid object based on a digital model. One approach to 3D printing is “stereolithography,” in which solid objects are created by successively “printing” thin layers of a curable polymer resin, first onto a substrate and then one atop another. In traditional systems, a layer is pointwise deposited and then hardened by exposure to actinic radiation, following which the next layer of liquid resin is deposited thereover. While the technology has improved in many ways over the years, there exist many hurdles that have not been overcome, specifically in the areas of cost and accessibility. 3D printers remain for the most part expensive to manufacture and sell. They may also be complicated to operate.

The steps involved in a 3D printing operation typically begin with user selection of a 3D model in a .STL or other supported format. The object represented by the selected model may be configured or optimized for a specific 3D printer using, for example, a personal computer. Configuration can involve, e.g., locating and orienting the part in space and creation of support structures needed for the object to be printed successfully. Often multiple parts can be placed in the 3D build volume of the printer. Driver software transfers the print job—i.e., the modified digital model—to the 3D printer itself. Before printing begins, the user inserts or cleans a “build platform” on which the object is printed, and provides material for printing. During printing, user interaction with the printer is usually limited, although s/he may monitor progress by, for example, looking through a window. After the object has been printed, the build platform is removed from the printer, and the printed object is separated from the build platform and from any support structure. The removal process can be delicate, requiring the use of various of tools in order not to damage the printed object. A cleaning process is usually required to obtain a high-quality print. In stereolithography, for example, the printed object may be subjected to a wash solution to remove excess resin and, in some instances, a post-cure exposure step whereby the object is bathed in actinic radiation to promote full cure.

One common source of error in 3D printing is misalignment of the build platform with respect to the resin source, resulting in error in the directional travel vector of the build platform or the resin source; this, in turn, compromises the ability to print objects that are dimensionally accurate and without accumulating error along the x and y axes. Similarly, imperfections in the flatness of the build platform surface compromise the accuracy of deposition and jeopardize adhesion of the resin to the build platform.

### SUMMARY

The present invention relates to 3D printing systems and methods that avoid build-compromising misalignments. Embodiments of the invention utilize a self-leveling assembly that establishes and maintains a constant and typically fully parallel orientation between a deposition mechanism and the build platform. In some embodiments, the deposition mechanism is an inkjet or other nozzle-terminated ejection system configured for two-dimensional (2D) scanning in a plane parallel to the build platform. In other embodiments, the system is configured for “reverse stereolithography,” in which a liquid resin surrounding the build platform is pointwise hardened thereagainst. In this case, the parallel orientation is maintained between the build platform and an opposed surface, e.g., the bottom of a resin tank. Implementations in accordance herewith compensate for error in the directional travel vector of either or both of the opposed surfaces as well as for errors in the flatness of either surface.

As used herein, the term “substantially” or “approximately” means ±10% (e.g., by weight or by volume), and in some embodiments, ±5%. The term “consists essentially of” means excluding other materials that contribute to function, unless otherwise defined herein. The term “light” refers to any form of electromagnetic radiation and not merely, for example, to visible light. Reference throughout this specification to “one example,” “an example,” “one embodiment,” or “an embodiment” means that a particular feature, structure, or characteristic described in connection with the example is included in at least one example of the present technology. Thus, the occurrences of the phrases “in one example,” “in an example,” “one embodiment,” or “an embodiment” in various places throughout this specification are not necessarily all referring to the same example. Furthermore, the particular features, structures, routines, steps, or characteristics may be combined in any suitable manner in one or more examples of the technology. The headings provided herein are for convenience only and are not intended to limit or interpret the scope or meaning of the claimed technology.

The following detailed description together with the accompanying drawings will provide a better understanding of the nature and advantages of the present invention.

### BRIEF DESCRIPTION OF THE DRAWINGS

FIG. 1 is a perspective view of a system environment in which embodiments of the present invention may be deployed.

FIG. 2 is a partially cut-away elevation of the system illustrated in FIG. 1.

FIG. 3 is a close-up elevation of certain components of a self-leveling tank in accordance with embodiments of the present invention.

FIG. 4 is a close-up perspective view showing the operation of a series of ball spring plungers in accordance with an embodiment of the invention.

### DETAILED DESCRIPTION

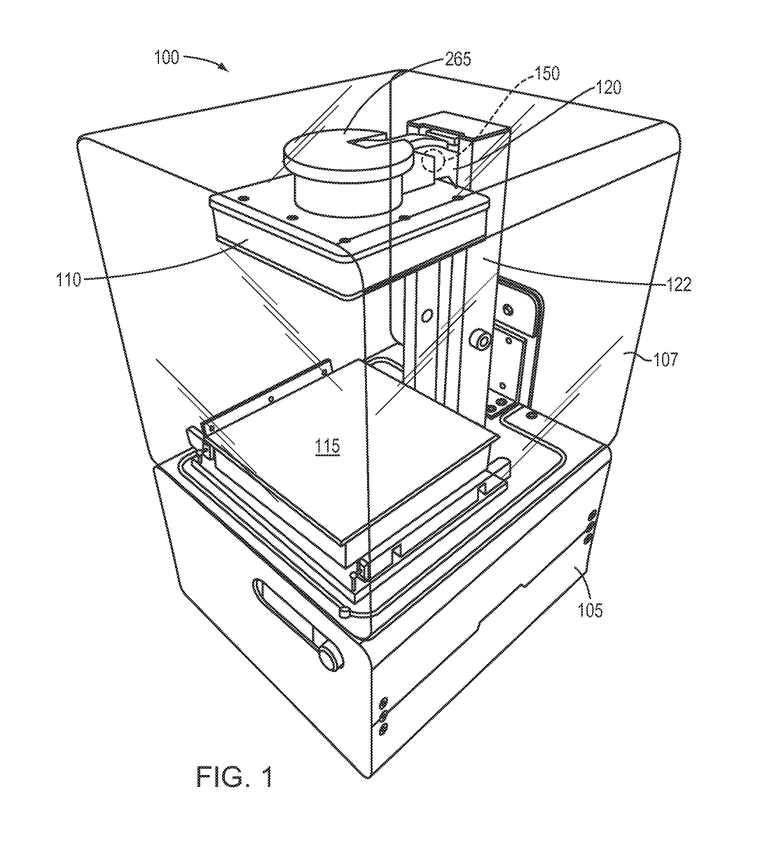

Refer first to FIG. 1, which illustrates a representative stereolithography system 100. The system includes a base housing 105 containing various mechanical, optical, electrical and electronic components that operate the system 100. A transparent upper housing 107 surrounds the build platform and a resin tank 115, which is sized to receive the build platform 107 therein, as discussed below. The build platform 110 is secured to a carriage 120 configured for vertical movement along a gantry 122; movement of the carriage 120 along the gantry 122 is controlled by drive components (not shown) within the gantry 122 and the base housing 105.

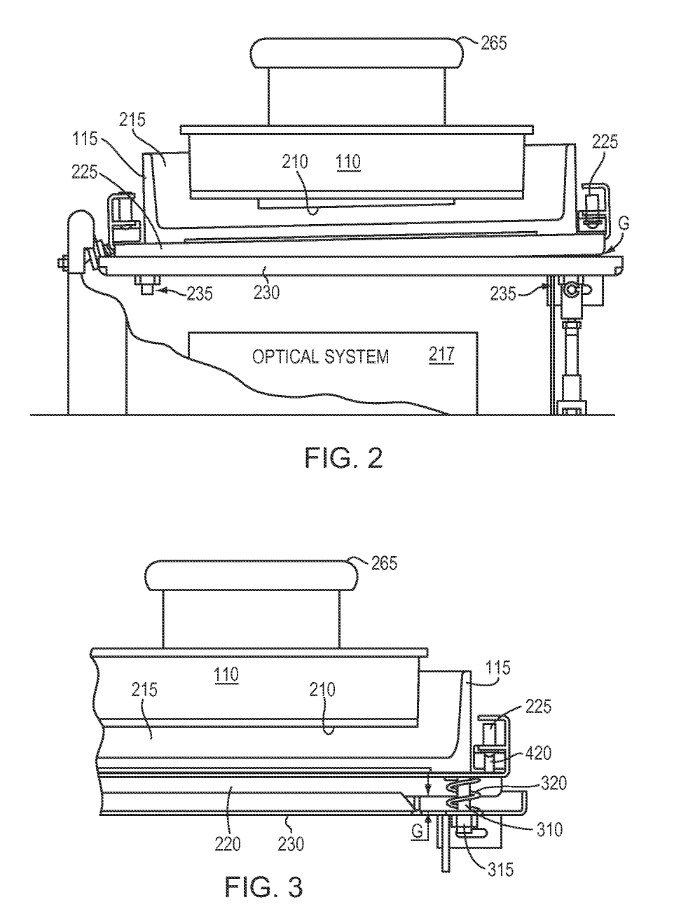

Operation of the system 100 may be understood with reference to FIGS. 1 and 2. The illustrated system utilizes a reverse stereolithography process by which an object is built up in layers on a downwardly facing receiving surface 210 of the build platform 110. In an initial configuration, the build platform 110 is fully submerged within the resin tank 115 so that the surface 210 is in contact with the bottom surface 215 of the tank 115. Typically the surface 215 is made of a compliant elastomeric material, such as a silicone (e.g., polydimethysiloxane, or PDMS). The bottom surface 215, and indeed all surfaces between the tank 115 and the internal components within the bottom housing 107, are transparent to actinic radiation, generally provided by a laser, capable of curing liquid resin within the tank 115. For example, a conventional ultraviolet laser and drive components within the bottom housing 107, collectively indicated at 217, may cooperate with movable mirrors that scan the beam from below over the bottom surface 210 of the build platform 210. The beam is selectively activated during movement of the mirrors so that pulses are delivered in a pointwise or “imagewise” pattern corresponding to the bottom layer of the object to be printed. The beam, where activated, cures the resin to create a solid element of material against, and adhering to, the receiving surface 210. When this layer is completed, the height of the build platform 110 is raised slightly along the gantry 122 so that another solid layer can be cured by the laser to adhere to the previously deposited layer. The process is repeated until the 3D object is fully formed, suspended upside-down from the surface 210.

Embodiments of the present invention are directed to retaining the tank 115—in particular its bottom surface 215—in parallel relation with the build surface 210 and, as well, with the optical components 217 directing the laser beam. It should be understood, however, that the principles hereof may be applied to other 3D printing architectures, e.g., utilizing a deposition print head that must be maintained in parallel relation with a build surface.

In the representative embodiment shown in FIGS. 2-4, the resin tank 115 is secured to a carrier tray 220 by force applied by a series of ball-spring plungers 225 as described below. The carrier tray 220, in turn, is suspended above the top surface of a larger support tray 230 by a series of spring-loaded connectors 235; in the illustrated embodiment, there are four such connectors each located at a corner of the tank carrier tray 220. With particular reference to FIG. 3, each of the connectors 235 may be a threaded stud 310. The head of each threaded stud 310 is mechanically or adhesively affixed to the tank carrier tray 220. The shanks of the threaded studs 310 pass through orifices in the support tray 220, and are free to slide vertically through these orifices. Vertical travel of the shanks through the respective orifices is limited by lock nuts 315 located below the support tray 230; as a result, the tank carrier tray 220 and the support tray 230 are loosely connected with a gap G between them. This gap is bridged by springs 320 along the shanks of the studs 310 intervening between the trays 220, 230 and urging them away from each other. The springs 320 apply a preload force that keeps the trays 220, 230 apart (with tension against the lock nuts 315) and are compressible by vertical movement of the build platform 110.

As explained above, when the 3D printer 100 begins printing a new part, the build platform 110 descends until its build surface 210 presses against the floor elastomeric floor 215 of the tank 115, compressing the springs 320 separating the carrier and support trays 220, 230. With the springs 320 fully compressed, further downward force is applied to the build platform to squeeze any resin out from between the contacting surfaces. This provides an even flat surface between the resin tank and the build platform, which is necessary for accurate printing, even if errors in flatness exist between the tank floor 215 and the build surface 210; in such circumstances, the springs 320 will not compress evenly but instead have sufficient stiffness to conform the surfaces 210, 215 to each other so as to compensate for error arising from misalignment or small imperfections in flatness.

When the build platform 110 is raised, its surface eventually loses contact with the floor 215 of the tank 115. The studs 235 and lock nuts 315 are preferably uniformly sized so that the gap G between the trays 220, 230 is constant across the opposed areas; that is, the trays remain precisely parallel even if the springs 320 have slightly different stiffnesses (or if the stiffnesses vary over time with use), since as long as the springs have enough force to urge the trays apart, the identical connectors enforce a uniform distance between them. As a result, the gap G and the spatial orientation of the resin tank 115—which are established by the studs 235 and lock nuts 315—remain fixed as the build platform 110 rises. Any necessary adjustment can be accomplishing by tightening or loosening the lock nuts 315.

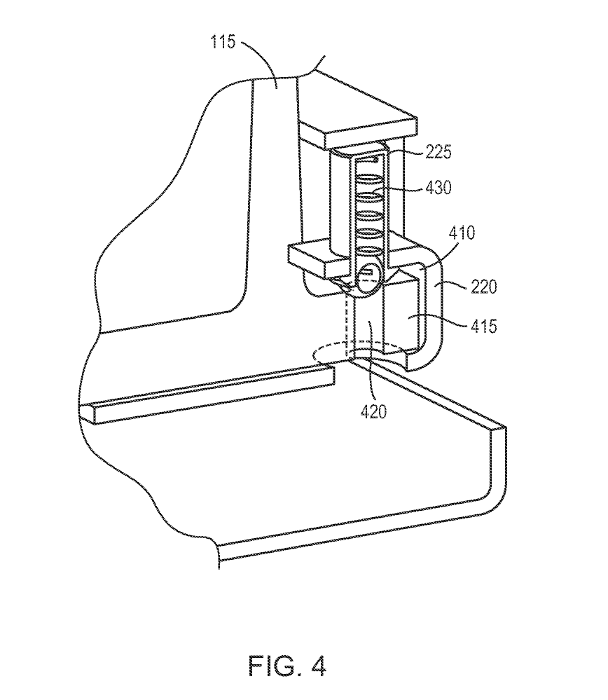

A spring-loaded coupling system facilitates easy removal and switching of resin tanks. As illustrated in FIG. 4, a slot 410 is located on each side the tank carrier tray 220. These slots 410 slidably receive complementary flanges 415, which project from the bottom side edges of the resin tank 115, as the tank slides into the carrier tray 220. The flanges 415 have a plurality of (e.g., two each) holes or depressions 420 which, when the tank 115 is fully inserted into the slots 410, align with the ball spring plungers 225 mounted to the tray 220. The head 425 of each of the plungers 225 is urged by an internal spring 430 against one of the tank flanges 415, and when the ball spring plungers 225 engage the holes 420, the heads 425 are forced into the holes 420 with an audible click, ensuring that the resin tank 115 maintains its location securely.

As will be appreciated by those having skill in the art, the inventive concepts in the above-described embodiment may be implemented in alternative ways. In one alternate embodiment, the mechanism depicted in FIGS. 2-4 is modified so as to attach the build platform 110 using the spring-loaded connecting system described above such that springs connecting the build platform to the apparatus provide an even flat surface between the resin tank 115 and the build platform 110. As above, the tank has a compliant layer 215 on its interior floor. The tank 115 is secured to a carrier tray 220 either in a conventional manner or using the spring-loaded connectors 225 described above. In this alternative embodiment, the build platform is attached to the retaining assembly 265 by means of one or more spring-loaded connectors. These connectors may be threaded studs. The head of each threaded stud is mechanically affixed to the build platform 110. The shanks of the threaded studs pass through orifices in the build-platform retaining assembly 265, and the shanks are free to slide vertically through these orifices. Vertical travel of the shanks through the respective orifices is limited by lock nuts; as a result, the build platform 110 and retaining assembly 265 are loosely connected with a gap between them. This gap is bridged by springs along the stud shanks intervening between the build platform 110 and the retaining assembly 265 and urging them away from each other. The springs apply a preload force that keeps the build platform 110 and retaining assembly 265 apart (with tension against the lock nuts) and are compressible by vertical movement of the build platform. As disclosed above, the build platform descends until it presses against the floor 215 of the tank 115, now compressing the springs separating the build platform 110 and the build platform retaining assembly 265. With the springs fully compressed, further downward force is applied to the build platform 110 that squeezes any resin out from between the contacting surfaces 210, 215. This provides an even flat surface between the resin tank and the build platform, even if errors in flatness exist between the tank floor 215 and the bottom surface 210 of the build platform 110; in such circumstances, the springs will not compress evenly but instead have sufficient stiffness to conform the surfaces to each other so as to compensate for error arising from misalignment or small imperfections in flatness. Once again, this approach may be applied to a other types of 3D printing systems, e.g., in which a print head, rather than the build platform, is affixed to the retaining assembly 265.

In yet another embodiment, the build platform 110 is mounted on a central ball joint 150 (see FIG. 1), which may be located within the retaining assembly 265, such that the platform 110 is free to rotate in order to align with the floor 215 of the resin tray 115. Springs or other elastic members may be attached at the corners of the build platform so as to provide a force restoring the orientation of the build platform 110 orientation when not pressed against the floor 215 of the resin tray 115. The ball joint may be used to fix the orientation of the build platform 110 relative to the z-axis, while allowing the build platform 110 to pivot in order to compensate for misalignment between the build platform and the resin tray 115. Alternatively, the ball joint may include an internal spring so as to also allow for movement in the z-axis direction. When the surfaces 210, 215 have been brought into proper alignment, the ball joint may be locked into place using a compression collar (or a simple clamp or screw); for example, the compression collar may be spring-loaded and operable by means of a grip or button, which the user releases to lock the ball joint.

In each of the disclosed embodiments, individual springs and retaining lock nuts may be replaced by alternate mechanical elements to provide compliance within the printing system. Springs, for example, may be functionally replaced with an elastic sheet, flexure bearing or other flexure element adhered or otherwise attached between the support and carrier trays. The use of an adhesive material in connection with an elastic sheet may advantageously reduce or eliminate the need for lock nuts or shanks to limit the range of motion. Alternatively, structural elements such as the carrier 120 or other mounting components may be designed with a flexible material or living hinge such to allow the surface 210 to accommodate to (i.e., align with) the tank floor 215 by virtue of vertical movement of the build platform 110. In such an alternative embodiment, the compressible structural elements function analogously to the springs in the embodiments disclosed above. As yet another embodiment, the mounting systems described above may be left free during an initial levelling and calibration step, but fixed after calibration such that the mounting points are substantially more rigid than during the calibration step. By increasing the rigidity of the mounting points during operation, the initial alignment and calibration can be advantageously preserved during operation.

Thus, although the invention has been described with respect to specific embodiments, it will be appreciated that the invention is intended to cover all modifications and equivalents within the scope of the following claims.

What is claimed is:

1. A self-leveling assembly adapted for use with a stereolithographic printing system including a vertically movable element having a downwardly facing horizontal surface, the self-leveling system comprising:
an open-topped vessel sized to receive the movable element and having an interior bottom surface at least a portion of which is configured for opposition to the downwardly facing horizontal surface of the movable element; and
an accommodative mechanism for causing alignment of the movable element with the bottom surface of the vessel upon contact therewith and retaining the alignment during vertical movement of the platform relative to the vessel.

2. The system of claim 1 wherein the vertically movable element is a platform for receiving thereon deposited material cumulatively forming a three-dimensional structure.

3. The system of claim 1 further comprising:
a carrier tray for supporting the vessel, the carrier tray having a substantially flat surface in substantially flush contact with a substantially flat exterior bottom surface of the vessel; and
a support tray disposed beneath the carrier tray,
wherein the accommodative mechanism comprises a plurality of spring connectors joining the support tray to the carrier tray and enforcing a uniform distance therebetween.

4. A stereolithographic printing system comprising:
a vertically movable platform having a downwardly facing horizontal surface;
an open-topped vessel sized to receive the platform and having an interior bottom surface at least a portion of which is configured for opposition to the downwardly facing horizontal surface of the movable platform; and
an accommodative mechanism for causing alignment of the platform with the bottom surface of the vessel upon contact therewith and retaining the alignment during vertical movement of the platform.

5. The system of claim 4 wherein the downwardly facing horizontal surface is a build surface for receiving thereon deposited material cumulatively forming a three-dimensional structure.

6. The system of claim 5 further comprising an optical system for causing deposition, in a pattern corresponding to a layer of an object to be printed, of a resin material in the vessel against the build surface, wherein the interior bottom surface of the vessel is transparent to actinic radiation emitted by the optical system.

7. The system of claim 4 wherein the accommodative mechanism comprises a plurality of spring connectors.

8. The system of claim 7 further comprising:
a carrier tray for supporting the vessel, the carrier tray having a substantially flat surface in substantially flush contact with a flat exterior bottom surface of the vessel; and
a support tray disposed beneath the carrier tray,
wherein (i) the spring connectors join the support tray to the carrier tray and enforce a uniform distance therebetween and (ii) at least a portion of the carrier tray is transparent to actinic radiation emitted by the optical system.

9. The system of claim 4 wherein the accommodative mechanism facilitates movement of the platform to an aligned position and fixed retention thereof.

10. The system of claim 9 wherein the accommodative mechanism comprises a ball joint.

11. A method of printing a three-dimensional object onto a build platform using a printing system comprising a surface, opposed to a surface of the build platform, facilitating deposition of material onto the build platform surface, the method comprising the steps of:
causing the build platform surface to contact the deposition-facilitating surface in order to align the surfaces;
stepwise separating the surfaces and depositing successive layers of solid material onto the build surface, the successive layers forming the object; and
retaining alignment between the surfaces until the object is formed notwithstanding the stepwise separation therebetween.

12. The method of claim 11 wherein the deposition-facilitating surface is a transparent floor of a vessel containing a radiation-curable resin, the depositing step comprising, for each layer, (i) scanning a laser beam through the floor of the vessel and selectively activating the laser during the scan to pointwise deposit cured particles of resin on the build platform surface in a pattern corresponding to the layer of the object, and (ii) increasing a separation between the floor of the vessel and the build platform surface, wherein alignment is retained notwithstanding the separation.

13. The method of claim 11 wherein the deposition-facilitating surface is a print head, the depositing step comprising, for each layer, (i) scanning the print head over the build surface and selectively activating the print head during the scan to deposit particles of resin on the build platform surface in a pattern corresponding to the layer of the object, and (ii) increasing a separation between the print head and the build platform surface, wherein alignment is retained notwithstanding the separation.

14. The method of claim 11 wherein alignment is retained by an accommodative mechanism operative on at least one of the build platform and the deposition-facilitating surface.

15. The method of claim 14 wherein the accommodative mechanism comprises a plurality of spring connectors.

16. The method of claim 14 wherein the accommodative mechanism comprises a ball joint.
